(19) United States
(12) Patent Application Publication
(10) Pub. No.: US 2025/0237726 A1
(43) Pub. Date: Jul. 24, 2025

(54) METHOD OF DOUBLE-CONTRAST MAGNETIC RESONANCE FINGERPRINTING

(71) Applicant: Zhejiang University, Hangzhou (CN)

(72) Inventors: Huafeng LIU, Hangzhou (CN); Shizhuo LI, Hangzhou (CN); Huihui YE, Hangzhou (CN)

(21) Appl. No.: 19/036,048

(22) Filed: Jan. 24, 2025

(30) Foreign Application Priority Data
Jan. 24, 2024 (CN) 202410100599.X

(51) Int. Cl. G01R 33/58; G01R 33/56; G01R 33/561

(52) U.S. Cl. CPC G01R 33/586; G01R 33/5601; G01R 33/5612

(57) ABSTRACT

A method of double-contrast magnetic resonance fingerprinting including: optimizing, using Cramér-Rao lower bound (CRLB) via a computer system, radiofrequency (RF) pulse parameters in an MRF sequence; loading, via the computer system, the RF pulse parameters optimized into an MRI scanner; and capturing raw k-space data by selecting different signal contrast modules for dual-contrast encoding at varying repetition times (TR); reconstructing, via the computer system, at least one image including a plurality of pixels; defining, via the computer system, a dynamic range and step size for tissue parameters; and creating, via the computer system, a dictionary based on Bloch equations, the dynamic range, and the step size; and comparing, via the computer system, signal evolution for each of the plurality of pixels in the at least one image to the dictionary to determine quantitative parameters for each of the plurality of pixels, and generating a quantitative parameter map.

### CROSS-REFERENCE TO RELATED APPLICATIONS

Pursuant to 35 U.S.C. § 119 and the Paris Convention Treaty, this application claims foreign priority to Chinese Patent Application No. 202410100599.X filed Jan. 24, 2024. The contents of all of the aforementioned applications, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, MA 02142.

### BACKGROUND

The disclosure relates to the field of magnetic resonance imaging (MRI) technology, and more specifically, to a method of double-contrast magnetic resonance fingerprinting.

Magnetic resonance technology utilizes the magnetic moment characteristics of atomic nuclei within molecules to perform qualitative, quantitative, and structural analysis of sample under investigation. Quantitative analysis of in vivo substance changes is critical for reflecting the occurrence and progression of human pathologies. Compared to conventional methods such as tissue biopsy, quantitative MRI offers several advantages, providing high contrast, and delivering high resolution.

Magnetic resonance fingerprinting (MRF) is a more precise quantitative MRI acquisition technique compared to the conventional methods. MRF encodes MRI signals by collecting pseudo-random variations in parameters, thereby enabling the acquisition of signals that contain multiple tissue parameters within a single scan. A signal evolution dictionary is created, and pattern matching techniques are applied to extract quantitative parameter values for each pixel in the acquired image, including longitudinal relaxation time (T₁) and transverse relaxation time (T₂), and T₂*. The quantitative parameter values are used to characterize the physiological properties of tissues and organs, offering significant value in both clinical diagnosis and scientific research.

During the MRF process, various acquisition sequences are used to gather the necessary data, including bSSFP (balanced Steady-State Free Precession), FISP (Fast Imaging with Steady-State Precession), and SPGR (Spoiled Gradient Echo). However, practical scanning reveals that the accuracy of T₂ quantification is more sensitive to the length of the acquisition sequences, and the quantification of T₂ is often less accurate than that of T₁.

To improve the accuracy of both the T₁ quantification and the T₂ quantification, the length of the acquisition sequence can be increased, and sampling rates can be reduced. However, the improvement results in longer signal acquisition time, which reduces patient diagnostic efficiency.

The MRF process typically involves setting the acquisition parameters such as flip angle (FA) and repetition time (TR) with pseudo-random variations based on empirical values. The acquisition parameters are not always optimized for the best possible performance. The issue of non-optimal parameter settings is addressed by incorporating Cramér-Rao lower bound (CRLB) optimization for the acquisition parameters. The application of CRLB optimization improves the accuracy of the quantification process, but with a trade-off: the accuracy of T₁ quantification may decrease slightly to achieve better performance for other parameters. Since MRF involves a high number of repetitions, automatic differentiation of Bloch simulations is utilized within the CRLB optimization process, enabling efficient and flexible optimization. Additionally, B-spline constraints are incorporated into the CRLB optimization framework to further improve computational efficiency, thus enhancing the overall performance of the MRF technique. The CRLB optimization method has already been developed and applied to other variants of MRF, such as sodium MRF, which is used for myelin quantification, and ultra-short TE MRF, which allows for measurements with very short echo times. The advancements show the feasibility and potential for improving the accuracy of the T₁ quantification and the T₂ quantification. Both T₁ and T₂ are fundamental and primary parameters in MRI. Despite the advancements, precise quantification of T₁ and T₂ remains a significant challenge.

### SUMMARY

To solve the aforesaid problems, the disclosure provides a method of double-contrast magnetic resonance fingerprinting (MRF).

The method comprises:
S1. optimizing, via a computer system, radiofrequency (RF) pulse parameters in an MRF sequence; wherein, the MRF sequence comprises a Fast Imaging with Steady-State Precession (FISP) contrast module and a Reversed Fast Imaging with Steady-State Precession (PSIF) contrast module;
S2. loading, via the computer system, the RF pulse parameters optimized into an MRI scanner; and capturing, using the MRI scanner, raw k-space data by selecting different signal contrast modules for dual-contrast encoding at varying repetition times (TR);
S3. reconstructing, via the computer system, at least one image comprising a plurality of pixels, by processing the raw k-space data using a reconstruction algorithm;
S4. defining, via the computer system, a dynamic range and step size for tissue parameters; and creating, via the computer system, a dictionary based on Bloch equations, the dynamic range, and the step size; and
S5. comparing, via the computer system, signal evolution for each of the plurality of pixels in the at least one image to the dictionary to determine quantitative parameters for each of the plurality of pixels, and generating a quantitative parameter map.

In a class of this embodiment, in S1, the RF pulse parameters comprise flip angle (FA), repetition time (TR), selection (SE), and flip angle multiplier (AM).

In a class of this embodiment, in S1, the FISP contrast module is configured to capture FISP signals, and the PSIF contrast module is configured to capture PSIF signals; the flip angle for the FISP contrast module is defined as FA, and the flip angle for the PSIF contrast module is defined as AM·FA; the SE parameter is introduced to determine, for each repetition time (TR), whether to select the FISP contrast module or the PSIF contrast module for capturing the MRF signal.

In a class of this embodiment, in S1, optimizing RF pulse parameters comprises setting longitudinal relaxation time (T₁) and transverse relaxation time (T₂) of the tissue parameters and the RF pulse parameters FA, TR, SE, and AM; inputting the tissue parameters and the RF pulse parameters into the Bloch equations to simulate the MRF signal; calculating, using the simulated MRF signal, a Fisher Information matrix; processing, using generalized inverse, the Fisher Information Matrix to compute a Cramer-Rao matrix; and creating a weighing matrix based on the tissue parameters T₁ and T₂; multiplying the weighing matrix with the Cramér-Rao matrix to produce a new matrix; and calculating a trace of the new matrix to derive an optimization objective function:

$${minimize}_{{T}_{1} , {T}_{2} , {M}_{0}} Tr ( WV ( θ ) ) ;$$

where, Tr represents the trace of the new matrix; W is the weighing matrix: W=diag ([1,1/T₁², 1/T₂²]); V(θ) is the Cramér-Rao matrix.

In a class of this embodiment, in S3, when the raw k-space data is collected from receiver coils, a parallel imaging method or a compressed sensing method is adopted to optimize the reconstruction of the at least one image.

In a class of this embodiment, in S4, creating a dictionary based on Bloch equations comprises: defining the dynamic range and step size for the tissue parameters T₁ and T₂; modeling, using the Bloch equations, the MRF signal for each unique combination of T₁ and T₂; and generating the dictionary; where, the dictionary comprises a plurality of entries; each of the plurality of entries corresponds to a unique combination of T₁ and T₂; the signal evolution for each of the plurality of entries is defined as a time-series response of the MRF signal modeled using the Bloch equations for the assigned tissue parameters T₁ and T₂; and the signal evolution is defined as follows:

$${m}_{fisp}^{n} = R ( {T}_{1} , {T}_{2} , {TE}_{n} ) Q ( {φ}_{n} , {α}_{n} ) {M}^{n - 1} + b ( {T}_{1} , {M}_{0} , {TE}_{n} ) ;$$

$${m}_{psif}^{n} = R ( {T}_{1} , {T}_{2} , ( {TR}_{n} - {TE}_{n} ) ) Q ( {φ}_{n} , AM \cdot {α}_{n} ) {M}^{n - 1} + b ( {T}_{1} , {M}_{0} , ( {TR}_{n} - {TE}_{n} ) ) ;$$

where, n is the n^{th} MRF signal measured at the n^{th} TR; m_{fisp}ⁿ and m_{psif}ⁿ are the n^{th} MRF signals collected from the FISP contrast module and the PSIF contrast module, respectively; R refers to a simulation of spin relaxation; Q refers to a simulation of signal excitation through the application of an RF pulse; b refers to a recovery of longitudinal magnetization; TE is an echo time between the application of the RF pulse and the detection of the MRF signal; φₙ and αₙ represent the phase and the flip angle of the RF pulse, respectively;
the SE parameter is rounded to determine which MRF signals to select from the FISP contrast module and the PSIF contrast module; the selected MRF signals are merged into a new MRF signal representing a combined result of the dual-contrast encoding at each TR; and the new signal can be expressed as follow:

$${m}^{n} = SE \cdot {m}_{fisp}^{n} + ( 1 - SE ) \cdot {m}_{psif}^{n}$$

where, mⁿ is the new MRF signal.

In a class of this embodiment, comparing signal evolution for each of the plurality of pixels in the at least one image to the dictionary comprises: inverting the PSIF signals; for each of the plurality of pixels, computing inner product between the signal evolution of the pixel and the signal evolution for each of the plurality of entries in the dictionary; summing all of absolute values of the computed inner products for each of the plurality of pixels; and selecting, for each of the plurality of pixels, an entry with the highest sum of absolute inner products as the best matching entry; and assigning the tissue parameters corresponding to the best entry as physical parameters of each of the plurality of pixels.

The following advantages are associated with the disclosure:

1. By incorporating the PSIF contrast module alongside the FISP contrast module, two types of signals are collected during the MRF scan. The method improve the precision of T₁ and T₂ quantification compared to methods that use only a single signal contrast module.

2. The disclosure utilizes the Cramér-Rao lower bound (CRLB) to optimize the RF pulse parameters such as the flip angle (FA), the repetition time (TR), the selection (SE), and flip angle multiplier (AM). The optimization improves the precision of T₁ and T₂ quantification and enhances the smoothness of the signal evolution. Compared to conventional FISP-based MRF fingerprinting methods, the disclosed method maintains the accuracy of T₁ quantification and enhances the accuracy of T₂ quantification.

3. In the disclosed method, the flip angle for the two signal contrast modules is set to different values to optimize the performance of each signal contrast module. Specifically, the AM parameter is introduced to represent the size of the flip angle used by the PSIF contrast module relative to the flip angle used by the FISP contrast module. By optimizing the AM parameter, the disclosed method improves the quality of reconstructed images and reduces the overall flip angle used in the FISP contrast module, leading to lower energy consumption during the scanning process.

### BRIEF DESCRIPTION OF THE DRAWINGS

FIG. 1 is a flowchart illustrating a method according to one example of the disclosure;

FIG. 2A is a diagram showing an MRF sequence according to one example of the disclosure;

FIG. 2B is a schematic diagram illustrating an FISP contrast module and a PSIF contrast module according to one example of the disclosure;

FIG. 3A is a diagram showing flip angle (FA) before and after CRLB optimization according to one example of the disclosure;

FIG. 3B is a diagram showing repetition time (TR) before and after CRLB optimization according to one example of the disclosure;

FIG. 3C is a diagram showing selection (SE) after CRLB optimization according to one example of the disclosure;

FIG. 4 is a comparison results of actual scanning experiments with simulation experiments for dual-contrast encoding according to one example of the disclosure;

FIG. 5 is a comparison chart showing normalized root mean square error (NRMSE) values for T₁ and T₂ in MRF sequences, based on simulation experiments; and

FIG. 6 shows results from dual-contrast encoding in actual scanning experiments according to one example of the disclosure.

### DETAILED DESCRIPTION

To further illustrate the disclosure, embodiments detailing the method of double-contrast magnetic resonance fingerprinting are described below. It should be noted that the following embodiments are intended to describe and not to limit the disclosure.

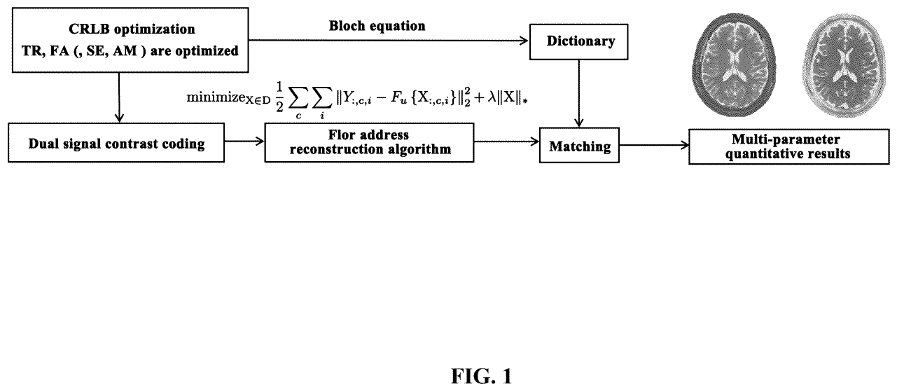

As shown in FIG. 1, a method of double-contrast magnetic resonance fingerprinting (MRF) comprises sequence optimization and data acquisition and processing.

### 1. Sequence Optimization

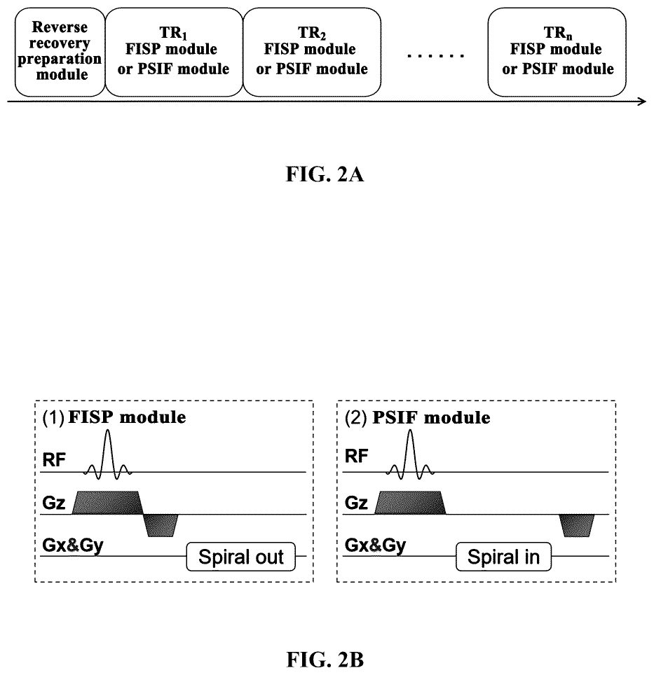

As shown in FIGS. 2A and 2B, the method comprises employing a FISP contrast module and a PSIF contrast module during an MRI scan.

A. The FISP contrast module emits the RF pulse to excite the hydrogen nuclei in the tissues. The nuclei relax and release energy. The energy is captured by the FISP contrast module as an FID signal.

B. In the PSIF contrast module, a rewinder gradient is applied at the end. A readout gradient in the PSIF contrast module is the time-reversed form of a readout gradient in the FISP contrast module. The signal from the previous contrast module is reemitted and refocused by the RF pulse in the current PSIF contrast module, resulting in an echo signal.

C. Different flip angles are used in the two contrast modules to obtain different echo signals. When alternatively using the two contrast modules, the echo signals are divided into two branches, one from each contrast module. The alternation usage of the two contrast modules is determined by introducing the SE parameter. The SE parameter is initialized using a trigonometric function to facilitate Cramér-Rao lower bound (CRLB) optimization. The trigonometric function can be expressed as follows:

$$SE = 0.5 cos ( π t ) + 0.5$$

The known values of the tissue parameters (T₁ and T₂) and the RF pulse parameters (FA, TR, SE, and AM) are input into the Bloch equations. The Bloch equations generate a simulated MRF signal that represents the expected MRF response of the tissue. The simulated MRF signal is configured to compute the Fisher Information matrix. The Fisher Information Matrix is configured to calculate the CRLB matrix. The CRLB matrix is configured to calculate an optimization objective function.

The Cramer-Rao Lower Bound (CRLB) is a theoretical limit that defines the minimum variance achievable by unbiased estimator when estimating a parameter. The CRLB matrix provide information that the variance of any unbiased estimator must be greater than or equal to the CRLB value. The variance of any unbiased estimator can be expressed as follows:

$$var ( \hat{θ} ) \geq V ( θ ) = \frac{1}{- E [ \frac{{\partial }^{2} ln p ( x ; θ )}{\partial {θ}^{2}} ]}$$

where, x is the acquired MRF signal; E is the mathematical expectation (average) of the acquired MRF signal; θ is the parameters to be optimized, such as TR and FA. V(θ) is the Fisher Information matrix.

In the CRLB optimization, upper bounds and lower bounds for the RF pulse parameters are defined as follows: FAₙ^{max°}, FAₙ^{min}=10°, TRₙ^{maxms}, TRₙ^{min}=16 ms, SEₙ^{max}, SEₙ^{min}=0, AMₙ^{max}, AMₙ^{min}=0. FA is the flip angle used in the FISP module; TR is the repetition time; SE is a parameter that determines the switching between the FISP and PSIF modules during the MRF sequence; and AM is the multiple of the flip angle used in the PSIF module compared to the FISP module.

Additionally, to ensure the smoothness of the signal evolution, a smoothing constraint is added to the CRLB optimization process: ΔF A^{max}=1°. The smoothing constraint helps avoid irregular or erratic behavior in the signal evolution, particularly when the data is undersampled.

The optimization objective function is defined as follows:

$$\text{?} Tr ( WV ( \text{?} ) )$$

$$s . t . {TR}_{n}^{min} \leq {TR}_{n} \leq {TR}_{n}^{max} , 1 \leq n \leq N ,$$

$${FA}_{n}^{min} \leq {FA}_{n} \leq {FA}_{n}^{max} , 1 \leq n \leq N ,$$

$$\vert F \text{?} - {FA}_{n} \vert \leq Δ {FA}^{max} , 1 \leq n \leq N ,$$

$${SE}_{n}^{min} \leq {SE}_{n} \leq {SE}_{n}^{max} , 1 \leq n \leq N ,$$

$${AM}_{n}^{min} \leq {AM}_{n} \leq {AM}_{n}^{max} , 1 \leq n \leq N .$$

$$\text{?} \text{indicates text missing or illegible when filed}$$

where, W is the weighing matrix: W=diag ([1,1/T₁², 1/T₂²]). The optimization objective function is a nonlinear, non-convex function. To solve the optimization objective function, an automatic differentiation-based least squares method is used. The process is carried out using Python software.

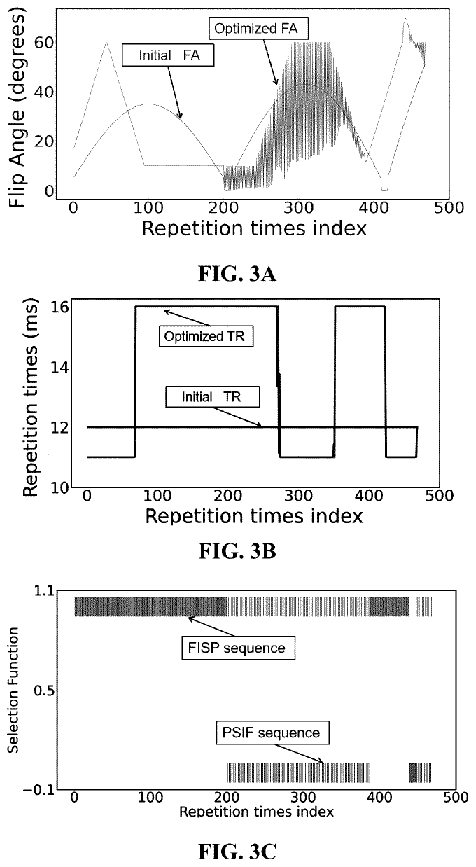

FIG. 3A displays the flip angle (FA) before and after the CRLB optimization. FIG. 3B shows the repetition time (TR) before and after the CRLB optimization. FIG. 3C is a plot showing the SE parameter after the CRLB optimization. In the plot, the top line represents the times when the FISP contrast module is selected, and the bottom line represents the times when the PSIF contrast module is selected.

### 2. Data Acquisition and Processing

A. The optimization results from FIGS. 3A-3C are used, and the total number of repetition times (TR) is set to 468. The MRF signal is acquired using a 2D variable-density spiral trajectory with 36 interleaves. The 2D variable-density spiral trajectory involves 2400 sampling points and completes the data acquisition in about 6.0 ms. The Field of View (FOV) is set to 220 mm, and the resolution is set to 1.25 mm. The setup of the acquisition parameters results in the collection of the k-space data. The MRF sequence is compiled on the Siemens IDEA platform and implemented on a Prisma 3.0T MRI scanner.

C. The basic principle of magnetic resonance fingerprinting (MRF) is to build a dictionary of fingerprints that represent all possible MRF signals, which are generated based on various tissue properties and parameters. The MRF signals in the dictionary are then compared with the actual MRF signals collected during an MRI scan. By identifying the fingerprint in the dictionary that most closely matches the collected MRF signal, the corresponding tissue physiological parameters, such as relaxation times (T₁ and T₂), can be determined. The process enables the creation of quantitative images, providing detailed information about tissue characteristics. The term “fingerprint”, as used herein, refers to the time evolution curve of the MRF signal. The dictionary is created as follows: (1) A range of variation for each parameter is defined, for example: T₁: [100:20:200 ms], [2100:100:3000 ms], [3200:500:5000 ms]; T₂: [10:5:150 ms], [160:10:200 ms], [220:20:300 ms], [400:100:2000 ms]; (2) Using the Bloch equations, all possible time evolution curves are computed based on the dynamic ranges of the tissue parameters. The time evolution curves forms the dictionary.

D. The k-space data is reconstructed into a plurality of images using the FLOR reconstruction algorithm. The reconstructed MRF signal is then compared with the entries in the dictionary by calculating the inner product. The inner product that yields the highest value indicates the entry in the dictionary that most closely matches the reconstructed MRF signal. The corresponding tissue parameters (T₁, T₂) for the entry are then assigned to the pixel, resulting in a quantitative parameter map for the entire image.

The experiment is split into two parts: simulation experiment and actual scanning experiment.

### (1) Simulation Experiments

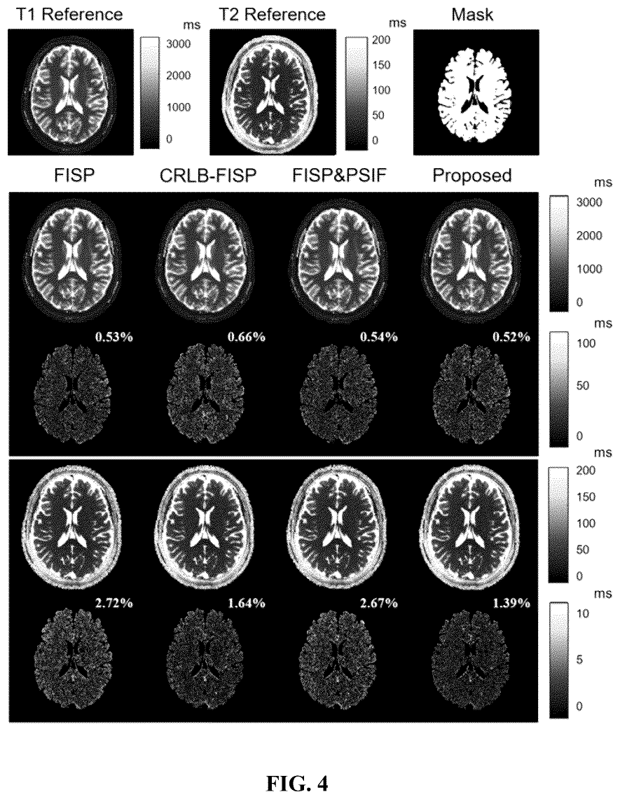

As shown in the top part of FIG. 4, a set of simulated brain images was constructed to serve as the ground truth for the experiment. A spiral sampling trajectory was used to mimic the data acquisition process. To make the simulation more realistic, Gaussian noise was added with a Signal-to-Noise Ratio (SNR) of 20. SNR is the ratio of the signal length to the noise intensity. The SNR formula is expressed as follows: SNR=101 g (s/σ)², where σ is the pre-set noise intensity and s is the average signal strength in the white matter region.

To compare the disclosed method, three other techniques were also tested, including conventional FISP sequences, CRLB-optimized FISP sequences, and a combination of FISP sequences and PSIF sequences. A mask was applied to isolate the region of interest in the brain. The deviation between the ground truth values and the results from the simulation was calculated as follows: bias=∥I−Î∥₂/∥I∥₂, where I and Î represent the quantitative true values and the simulated quantitative results, respectively.

The experimental results and error maps are shown in FIG. 4. The upper part of FIG. 4 displays the T₁ quantitative results and corresponding error maps. The lower part of FIG. 4 displays the T₂ quantitative results and corresponding error maps. The bias is shown in the upper-right corner of each error map. The experimental results indicate that when CRLB optimization is introduced, the accuracy of T₂ quantification improves. However, the improvement comes at the cost of a slight decrease in T₁ accuracy. By introducing dual-contrast encoding, the T₂ accuracy is further enhanced, although the improvement is limited. The best results are achieved when both CRLB optimization and dual-contrast encoding are combined. The combination maintains the accuracy of T₁ quantification while simultaneously improving the accuracy of T₂ quantification even further.

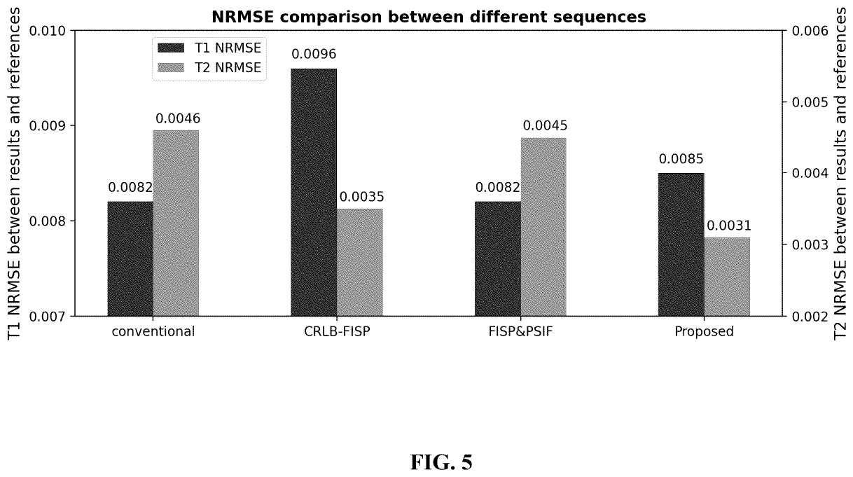

In FIG. 5, the normalized root mean square error (NRMSE) for the results of each sequence is displayed. The disclosed method outperforms other methods in both T₁ quantification and T₂ quantification. The method achieves the best T₂ accuracy with the lowest NRMSE and also provides improved T₁ accuracy when compared to the CRLB-optimized FISP method.

### (2) Actual Scanning Experiments

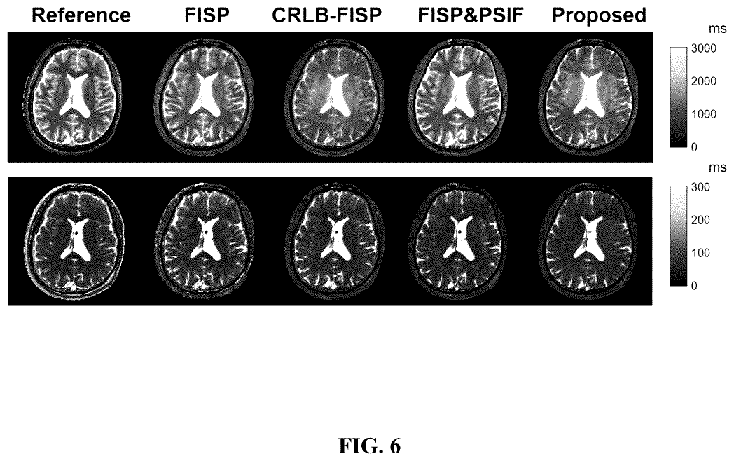

In vivo experiments were conducted using a Siemens Prisma 3.0T MRI scanner with a 20-channel head coil, with w. Written consent was obtained from healthy volunteers before the experiments. FIG. 6 shows the quantitative results obtained from various sequences. The reference sequence used in the experiment is the conventional FISP sequence with 12 interleaves. The quantitative results for the sequence were reconstructed using the gridding technique. When comparing the disclosed method to the reference sequence, the disclosed method shows notable improvements, particularly in the smoothness of the images. The improvement is especially evident in the quantification of T₂, where the image quality is smoother than in the reference sequence.

TABLE 1
Normalized standard deviation of the results

| | FISP | CRLB-FISP | FISP&PSIF | Proposed |
|---|---|---|---|---|
| T₁ Nstd | 1.32 | 1.28 | 1.35 | 1.36 |
| T₂ Nstd | 2.80 | 2.43 | 2.79 | 1.96 |

The tissue parameters and the RF pulse parameters are defined as follows:

T₁ (Longitudinal Relaxation Time): A parameter representing the time required for the longitudinal magnetization vector to recover to 67% of its total signal intensity after being disturbed by an RF pulse.

T₂ (Transverse Relaxation Time): A parameter representing the time required for the transverse magnetization vector to decay from 100% to 37% of its initial signal intensity due to interactions between nuclear spins, after the application of an RF pulse.

FA (Flip Angle): A parameter representing the angle by which the magnetization vector is deflected from its alignment with the main magnetic field by the excitation RF pulse. Specifically, when FA=90°, the magnetization vector is perpendicular to the main magnetic field direction.

TE (Echo Time): A parameter representing the time interval between the center of the RF excitation signal and the center of the received echo signal in the MRF sequence.

TR (Repetition Time): A parameter representing the time interval between two consecutive RF excitations in the MRF sequence, which controls the longitudinal relaxation process between excitations.

SE (Selection): A parameter that selects between the two signal contrast modules used in the MRF sequence. When SE=1, the FISP contrast module is selected, and when SE=0, the PSIF contrast module is selected.

AM (Flip Angle Multiplier): A parameter representing the multiplier factor by which the flip angle used in the PSIF contrast module is adjusted relative to the flip angle used in the FISP contrast module.

It will be obvious to those skilled in the art that changes and modifications may be made, and therefore, the aim in the appended claims is to cover all such changes and modifications.

What is claimed is:

1. A method of double-contrast magnetic resonance fingerprinting, comprising:
S1. optimizing, using Cramér-Rao lower bound (CRLB) via a computer system, radiofrequency (RF) pulse parameters in an MRF sequence;
wherein, the MRF sequence comprises a Fast Imaging with Steady-State Precession (FISP) contrast module and a Reversed Fast Imaging with Steady-State Precession (PSIF) contrast module;
S2. loading, via the computer system, the RF pulse parameters optimized into an MRI scanner; and capturing, using the MRI scanner, raw k-space data by selecting different signal contrast modules for dual-contrast encoding at varying repetition times (TR);
S3. reconstructing, via the computer system, at least one image comprising a plurality of pixels, by processing the raw k-space data using a reconstruction algorithm;
S4. defining, via the computer system, a dynamic range and step size for tissue parameters; and creating, via the computer system, a dictionary based on Bloch equations, the dynamic range, and the step size; and
S5. comparing, via the computer system, signal evolution for each of the plurality of pixels in the at least one image to the dictionary to determine quantitative parameters for each of the plurality of pixels, and generating a quantitative parameter map.

2. The method of claim 1, wherein in S1, the RF pulse parameters comprise flip angle (FA), repetition time (TR), selection (SE), and flip angle multiplier (AM).

3. The method of claim 1, wherein in S1, the FISP contrast module is configured to capture FISP signals, and the PSIF contrast module is configured to capture PSIF signals; the flip angle for the FISP contrast module is defined as FA, and the flip angle for the PSIF contrast module is defined as AM·FA; the SE parameter is introduced to determine, for each repetition time (TR), whether to select the FISP contrast module or the PSIF contrast module for capturing the MRF signal.

4. The method of claim 3, wherein optimizing RF pulse parameters comprises: setting longitudinal relaxation time (T₁) and transverse relaxation time (T₂) of the tissue parameters and the RF pulse parameters FA, TR, SE, and AM; inputting the tissue parameters and the RF pulse parameters into the Bloch equations to simulate the MRF signal; calculating, using the simulated MRF signal, a Fisher Information matrix; processing, using generalized inverse, the Fisher Information Matrix to compute a Cramér-Rao matrix; and creating a weighing matrix based on the tissue parameters T₁ and T₂; multiplying the weighing matrix with the Cramer-Rao matrix to produce a new matrix; and calculating a trace of the new matrix to derive an optimization objective function:
$${minimize}_{{T}_{1} , {T}_{2} , {M}_{0}} Tr ( WV ( θ ) ) ;$$
where, Tr represents the trace of the new matrix; W is the weighing matrix: W=diag ([1,1/T₁², 1/T₂²]); and V(θ) is the Cramér-Rao matrix.

5. The method of claim 1, wherein in S3, when the raw k-space data is collected from receiver coils, a parallel imaging method or a compressed sensing method is adopted to optimize the reconstruction of the at least one image.

6. The method of claim 1, wherein in S4, creating a dictionary based on Bloch equations comprises: defining the dynamic range and step size for the tissue parameters T₁ and T₂; modeling, using the Bloch equations, the MRF signal for each unique combination of T₁ and T₂; and generating the dictionary; wherein, the dictionary comprises a plurality of entries; each of the plurality of entries corresponds to a unique combination of T₁ and T₂; the signal evolution for each of the plurality of entries is defined as a time-series response of the MRF signal modeled using the Bloch equations for the assigned tissue parameters T₁ and T₂; and the signal evolution is defined as follows:
$${m}_{fisp}^{n} = R ( {T}_{1} , {T}_{2} , {TE}_{n} ) Q ( {φ}_{n} , {α}_{n} ) {M}^{n - 1} + b ( {T}_{1} , {M}_{0} , {TE}_{n} )$$
$${m}_{psif}^{n} = R ( {T}_{1} , {T}_{2} , ( {TR}_{n} - {TE}_{n} ) ) Q ( {φ}_{n} , AM \cdot {α}_{n} ) {M}^{n - 1} + b ( {T}_{1} , {M}_{0} , ( {TR}_{n} - {TE}_{n} ) )$$
where, n is a n^{th} MRF signal measured at the n^{th} TR; m_{fisp}ⁿ and m_{psif}ⁿ are n^{th} MRF signals collected from the FISP contrast module and the PSIF contrast module, respectively; R refers to a simulation of spin relaxation; Q refers to a simulation of signal excitation through an application of an RF pulse; b refers to a recovery of longitudinal magnetization; TE is an echo time between the application of the RF pulse and the detection of the MRF signal; φₙ and αₙ represent a phase and a flip angle of the RF pulse, respectively;
SE parameter is rounded to determine which MRF signals to select from the FISP contrast module and the PSIF contrast module; the MRF signals selected are merged into a new MRF signal representing a combined result of the dual-contrast encoding at each TR; and a new signal is expressed as follow:
$${m}^{n} = SE \cdot {m}_{fisp}^{n} + ( 1 - SE ) \cdot {m}_{psif}^{n}$$
where, mⁿ is the new MRF signal.

7. The method of claim 1, wherein in S5, comparing signal evolution for each of the plurality of pixels in the at least one image to the dictionary comprises: inverting PSIF signals; for each of the plurality of pixels, computing an inner product between the signal evolution of the pixel and the signal evolution for each of the plurality of entries in the dictionary; summing all of absolute values of the computed inner products for each of the plurality of pixels; and selecting, for each of the plurality of pixels, an entry with the highest sum of absolute inner products as the best matching entry; and assigning the tissue parameters corresponding to a best entry as physical parameters of each of the plurality of pixels.
